(19) United States
(12) Patent Application Publication
(10) Pub. No.: US 2025/0309861 A1
(43) Pub. Date: Oct. 2, 2025

(54) OSCILLATOR WAFER-LEVEL-PACKAGE STRUCTURE AND OSCILLATOR CRYSTAL STRUCTURE HAVING INTERNAL CUT-OFF REGION THEREOF

(71) Applicant: TXC CORPORATION, Taipei (TW)

(72) Inventors: Chih-Hsun CHU, Ping Cheng City (TW); Chih-Hung CHIU, Ping Cheng City (TW); Hsiang-Jen CHENG, Ping Cheng City (TW); Ming-Yi YANG, Ping Cheng City (TW); Wun-Kai WANG, Ping Cheng City (TW)

(73) Assignee: TXC CORPORATION, Taipei (TW)

(21) Appl. No.: 18/663,488

(22) Filed: May 14, 2024

(30) Foreign Application Priority Data
Mar. 27, 2024 (TW) 113111561

(51) Int. Cl. H03H 9/17; H03B 5/32; H03H 9/13

(52) U.S. Cl. CPC H03H 9/17; H03B 5/32; H03H 9/13

(57) ABSTRACT

An oscillator wafer-level-package structure and oscillator crystal structure having internal cut-off region thereof are provided. At least one cut-off region is formed inside the oscillator crystal structure, penetrating its upper and lower surface, such that the crystal main region and its adjacent region are separated. A bottom layer includes an upper plane. A capping layer includes a lower plane, and the oscillator crystal structure is disposed there in between, forming an upper and lower cavity with the capping layer and the bottom layer. By engaging an upper and lower seal ring surrounding the oscillator crystal structure, the oscillator crystal structure is sealed, forming the wafer-level-package structure. By designing internal cut-off region inside the oscillator crystal structure, frequency offset after encapsulation is reduced, and better device characteristics are obtained.

### BACKGROUND OF THE INVENTION

This application claims priority for the TW patent application No. 113111561 filed on 27 Mar. 2024, the content of which is incorporated by reference in its entirely.

### FIELD OF THE INVENTION

The present invention is related to an oscillator wafer-level-package (WLP) structure. More particularly, it is related to a WLP structure for an oscillator crystal characterized by having at least one internal cut-off region therein and the internal cut-off region is implemented by adopting an etching process.

### DESCRIPTION OF THE PRIOR ART

As known, in accordance with the trend of system integration, a variety of electronic systems nowadays are equipped with clock components, and integrating the clock components with sensing elements into the electronic systems has become one of the mainstream technologies in semiconductor packaging technical field. Since taking a quartz crystal piezoelectric element as an oscillator provides an outstanding accuracy and stability, a quartz crystal is mostly adopted for performing as a clock component in the current practice. According to the International Electrotechnical Commission (IEC), quartz-crystal-piezoelectric-element oscillators include four categories: simple package crystal oscillators (SPXO), voltage-controlled crystal oscillators (VCXO), temperature-compensated crystal oscillators (TCXO) and oven-controlled crystal oscillators (OCXO). However, with the rapid developments of the IC industries, it is believed that electronic products tend to show more functions, higher performances, and lighter weight. As such, in order to meet the packaging requirements for high-intensity integration and miniaturization of semiconductor IC chips, it is obvious that the existing packaging technologies are no longer adequate.

In general, in accordance with the miniaturization of semiconductor piezoelectric devices, the quartz crystal and the integrated circuit are usually respectively packaged along with ceramic materials first, and the subsequent electrical connections are successively performed by employing the current existing technologies. However, since the packaging materials may melt due to heat and therefore cause a short circuit, or the quartz crystal may decline to contact with its bottom base layer, the existing packaging structure usually has a cavity on the surface of its bottom base layer so as to use such cavity for accommodating the quartz crystal.

However, due to the constraints of the cavity spacing and the process capability of the bottom base layer, it cuts off the area for providing sufficient electrical connections in the piezoelectric elements and makes the test process performed for the piezoelectric elements much more difficult, thereby causes decrease in the testing yields.

In addition, regarding the current wafer-level packaging technology, it is known that most or all of the packaging and testing procedures will be performed directly on the wafer, and after that, singulation will be employed to further define a single component. Among them, the process techniques of wiring redistribution and conductive bumping layouts are the general methodologies for its signal input and output implementations. Since the WLP structure is advantageous of having smaller packaging size and showing better electrical performances, it can be widely applied to electronic devices requiring light, thin and tiny volume. And as the user demands are getting higher, it is believed that the size of every component within the electronic packaging structures must be also reduced. As such, in order to significantly reduce the shortcomings and limitations caused by traditional two-dimensional packaging technology, the developments of three-dimensional packaging technology are greatly pursued and invested instead, in the recent years by the related industries and many researches. Regarding the three-dimensional packaging technologies, it is known that the TSV (through silicon via) process is effective for providing electrical connections in a vertical way within a wafer structure, such that the electrical transmitting length can be shortened, which makes such packaging technologies much more prominent and valued in the technical field. However, even though, it draws people's attention that a reduced dimension, will at the same time, create thermal expansion coefficients mismatch between different materials used in the wafer packaging structure. Moreover, the heat dissipation issue due to case temperature, as well as thermal stress concentration occurred in the wafer packaging structure are also deficiencies which are expected to be overcome. Further improvements and alternative methodologies in the field are still to be found.

As a result, it, in view of all, should be apparent and obvious that there is indeed an urgent need for the professionals in the field for a novel and inventive WLP structure to be developed, so as to avoid the above-mentioned issues in a way and solving the conventional problems at the same time. In particular, please proceed to find a complete and full detailed specific description and several implementations, which are now to be provided by the Applicants of the present invention in the following paragraphs in the below for your references.

### SUMMARY OF THE INVENTION

In order to overcome the above-mentioned disadvantages, one major objective in accordance with the present invention is provided for a novel and modified oscillator crystal structure, which is characterized by having at least one internal cut-off region formed in the oscillator crystal structure. According to the present invention, the modified oscillator crystal structure comprises a crystal main region, a first adjacent region which is disposed adjacent to one side of the crystal main region, and a second adjacent region which is opposite to the first adjacent region and disposed adjacent to another side of the crystal main region. The crystal main region includes an upper surface and a lower surface opposite to the upper surface. A maximum thickness of the first adjacent region and the second adjacent region is greater than a crystal thickness of the crystal main region, such that an upper cavity is formed between a top surface of the first adjacent region and the second adjacent region and the upper surface of the crystal main region, and a lower cavity is formed between a bottom surface of the first adjacent region and the second adjacent region and the lower surface of the crystal main region.

At least one cut-off region is formed between the crystal main region and the first adjacent region. Alternatively, the cut-off region may also be optionally formed between the crystal main region and the second adjacent region. As a result, by such configurations, the crystal main region and the first adjacent region, or the crystal main region and the second adjacent region can be separated.

According to the present invention, the disclosed cut-off region, for instance, can be formed by adopting a dry etching process or a wet etching process.

In one embodiment, the disclosed cut-off region can be formed between the crystal main region and the first adjacent region, such that the crystal main region and the first adjacent region are separated.

In another embodiment, the disclosed cut-off region can alternatively be formed between the crystal main region and the second adjacent region, such that the crystal main region and the second adjacent region are separated.

In further another embodiment, the disclosed cut-off region may also be alternatively formed between the crystal main region and the first adjacent region and between the crystal main region and the second adjacent region, such that the crystal main region, the first adjacent region and the second adjacent region are separated.

More specifically, the disclosed cut-off region is configured to be extending from the upper surface to the lower surface of the crystal main region, forming a penetration between the upper surface and the lower surface. In addition, when practically applied, a width of the disclosed cut-off region is adjustable. For instance, in one embodiment, when the cut-off region has a first width, the first adjacent region or the second adjacent region has a protrusion which is closed to the crystal main region. On the other hand, when the cut-off region has a second width, the first adjacent region or the second adjacent region has a straight edge which is closed to the crystal main region. The second width is greater than the first width. In other words, it is believed that according to the present invention, the cut-off region formed by employing the technical solution of the present invention has an adjustable width, such that a variety of edge shape of the first and/or second adjacent region closed to the crystal main region is feasible. For instance, the edge shape may be, and yet not limited to a protrusion, a straight edge, a concave, or the like. In general, those skilled in the art and having general knowledge are able to make appropriate modifications or variations with respective to the technical contents disclosed in the present invention without departing from the spirits of the present invention. The present invention is not restricted by the certain limited configurations and/or structural diagrams disclosed in the embodiments of the present invention. As such, it is believed that the modifications or variations should still fall into the scope of the present invention, and the present invention covers the modifications and its equality.

In another aspect, the present invention further provides a novel oscillator wafer-level-package (WLP) structure. The proposed oscillator wafer-level-package structure is inventive and modified to use a bottom layer and a capping layer both having a flat plane for encapsulating the oscillator crystal structure. Therefore, the constraints of the process capability of the bottom base layer and difficulties for test process to be performed due to less contact area of the piezoelectric elements with the bottom base layer as mentioned in the prior arts, can be avoided. By adopting the proposed oscillator wafer-level-package structure, it discloses a bottom layer, a capping layer and an oscillator crystal structure. The bottom layer includes an upper plane. The capping layer includes a lower plane. And the oscillator crystal structure is disposed between the bottom layer and the capping layer, and the oscillator crystal structure is in contact with the upper plane of the bottom layer and the lower plane of the capping layer. The disclosed oscillator crystal structure comprises: a crystal main region, including an upper surface and a lower surface opposite to the upper surface; a first adjacent region, being disposed adjacent to one side of the crystal main region; and a second adjacent region, opposite to the first adjacent region and disposed adjacent to another side of the crystal main region. A maximum thickness of the first adjacent region and the second adjacent region is greater than a crystal thickness of the crystal main region, such that an upper cavity is formed between a top surface of the first adjacent region and the second adjacent region and the upper surface of the crystal main region, and a lower cavity is formed between a bottom surface of the first adjacent region and the second adjacent region and the lower surface of the crystal main region. At least one cut-off region is formed between the crystal main region and the first or the second adjacent region, such that the crystal main region and the first or the second adjacent region are separated. In the meantime, the upper cavity is sealed between the upper surface of the crystal main region and the lower plane of the capping layer, and the lower cavity is sealed between the lower surface of the crystal main region and the upper plane of the bottom layer. The oscillator crystal structure is sealed and packaged between the capping layer and the bottom layer.

According to the present invention, an upper seal ring is further formed between the lower plane of the capping layer and the oscillator crystal structure. A lower seal ring is further formed between the upper plane of the bottom layer and the oscillator crystal structure. The upper seal ring and the lower seal ring are respectively surrounding the oscillator crystal structure such that the oscillator crystal structure is sealed in between the capping layer and the bottom layer by employing the upper seal ring and the lower seal ring.

In detailed configurations, the disclosed upper seal ring is formed between the lower plane of the capping layer and the top surface of the first adjacent region and the second adjacent region of the oscillator crystal structure. And the disclosed lower seal ring is formed between the upper plane of the bottom layer and the bottom surface of the first adjacent region and the second adjacent region of the oscillator crystal structure. In addition, the disclosed upper seal ring and the lower seal ring are respectively surrounding the crystal main region of the oscillator crystal structure, specifically.

And in the upper seal ring and the lower seal ring, two interface metal layers and one connecting metal layer are provided. The two interface metal layers of the upper seal ring are connected with the lower plane of the capping layer and the top surface of the oscillator crystal structure, respectively. The two interface metal layers of the lower seal ring are connected with the upper plane of the bottom layer and the bottom surface of the oscillator crystal structure, respectively. A diffusion barrier is further disposed between each of the interface metal layers and the connecting metal layer. And, the diffusion barrier, for example, can be made of a material selected from a group consisting of ruthenium (Ru), titanium (Ti) or an alloy of Ru and Ti, organic polymers, and oxides.

In one preferred embodiment of the present invention, the interface metal layers can be made of chromium (Cr). The connecting metal layer can be made of gold (Au), tin (Sn) or an alloy of Au and Sn. It is believed that another objective in accordance with the present invention is to provide an oscillator wafer-level-package structure, in which a diffusion barrier is further provided between the interface metal layer and the connecting metal layer of the seal rings. The diffusion barrier can be made of a material selected from a group consisting of Ru, Ti or Ru—Ti alloy, organic polymers, and oxides for preventing interface diffusion.

And furthermore, for an optimization of package structure stress intensity, in one embodiment of the present invention, the capping layer, the bottom layer and the oscillator crystal structure are designed to have the same or similar thermal expansion coefficient in order to prevent the thermal stress issues when sealing the package structure. For instance, the thermal expansion coefficient of the capping layer and the bottom layer disclosed by the present invention can be in a range between 2*10⁻⁷/K and 9*10⁻⁷/K. And furthermore, in a preferred embodiment of the present invention, a material of all the capping layer, the oscillator crystal structure and the bottom layer used in the oscillator wafer-level-package structure can be selected as quartz for optimizing the package structure stress intensity of the present invention. By designing the capping layer, the oscillator crystal structure and the bottom layer of the WLP structure to have the same or similar thermal expansion coefficient, the present invention succeeds in achieving an optimal thermal stress result when realizing the packaging structure.

And in addition, the proposed technical contents of the present invention can be further combined with TQV (Through Quartz via) technology to form at least one metal via. By employing the at least one metal via penetrating the wafer and providing electrical connections, high-density connections between process chips can be provided. And thus, an even more optimized integration technique between wafer manufacturing in the front-end process and packaging process in the back-end process is obtained. For example, according to one practical embodiment of the present invention, an upper exciting electrode and a lower exciting electrode can be further formed on the upper surface and the lower surface of the oscillator crystal structure, respectively. And the upper exciting electrode and the lower exciting electrode are respectively disposed in the sealed upper cavity and in the sealed lower cavity. A bottom metal layer is formed on an underneath layer of the bottom layer, and at least one via hole penetrates through the bottom layer such that the bottom metal layer extends upward to fill the at least one via hole and form at least one metal pillar so as to electrically connect to the upper exciting electrode, the lower exciting electrode and the bottom metal layer for providing signal inputs and outputs (I/O). In one embodiment, the bottom metal layer is made of copper (Cu), for instance. To sum above, it is apparent that the present invention provides effective electrical connections for the disclosed oscillator wafer-level-package structure.

As a result, based on the disclosed technical features illustrated as above, it is evident that the present invention is sophisticatedly designed and indeed discloses a novel modified scheme for an oscillator crystal structure and an oscillator wafer-level-package structure formed by using the same. According to the provided oscillator crystal structure, internal cut-off region is formed, such that its crystal main region is separate from its adjacent region due to the cut-off region. By employing the proposed oscillator crystal structure having internal cut-off region, it helps to reduce the frequency offset after packaging and shows better impedance and component characteristics. As a result, it is believed that the proposed invention is beneficial in view of a great number of merits. Thus, it is believed that the present invention is extremely advantageous while compared to the prior arts.

In the following, the applicants of the invention further provide detailed specific embodiments and accompanying drawings for illustrating the purpose, technical contents, characteristics and effects of the present invention for references.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings:

FIG. 1 schematically shows a cross sectional diagram of an oscillator crystal structure having internal cut-off region in accordance with a first embodiment of the present invention.

FIG. 2 schematically shows a cross sectional diagram of an oscillator crystal structure having internal cut-off region in accordance with a second embodiment of the present invention.

FIG. 3 schematically shows a cross sectional diagram of an oscillator crystal structure having internal cut-off region in accordance with a third embodiment of the present invention.

FIG. 4 schematically shows a cross sectional diagram of an oscillator wafer-level-package (WLP) structure encapsulating the oscillator crystal structure in view of FIG. 1.

FIG. 5 shows a cross sectional view of the upper seal ring according to the embodiment of the present invention.

FIG. 6 shows a cross sectional view of the lower seal ring according to the embodiment of the present invention.

FIG. 7 schematically shows a cross sectional diagram of an oscillator wafer-level-package (WLP) structure encapsulating the oscillator crystal structure in view of FIG. 2.

FIG. 8 schematically shows a cross sectional diagram of an oscillator wafer-level-package (WLP) structure encapsulating the oscillator crystal structure in view of FIG. 3.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

The embodiments described below are illustrated to demonstrate the technical contents and characteristics of the present invention and to enable the persons skilled in the art to understand, make, and use the present invention. However, it shall be noticed that it is not intended to limit the scope of the present invention. Therefore, any equivalent modification or variation according to the spirit of the present invention is to be also included within the scope of the present invention.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

The terms “substantially,” “around,” “about” and “approximately” can refer to within 20% of a given value or range, and preferably within 10%. Besides, the quantities provided herein can be approximate ones and can be described with the aforementioned terms if are without being specified. When a quantity, density, or other parameters includes a specified range, preferable range or listed ideal values, their values can be viewed as any number within the given range.

As the Applicants of the present invention have described earlier in the Description of the Prior Art, in order to form a WLP structure of an oscillator crystal which shows better device characteristics and maintain a low process complexity, the present invention is aimed to provide a modified oscillator crystal structure. The disclosed oscillator crystal structure is characterized by having at least one internal cut-off region, and through simulation analysis, it is proven that the present invention is beneficial to providing better internal thermal stress, thereby reducing the frequency offset after forming an encapsulation package structure. In view of the specific structural configurations, the applicants of the invention are providing relevant detailed descriptions for references through a plurality of variant embodiments described in the following paragraphs.

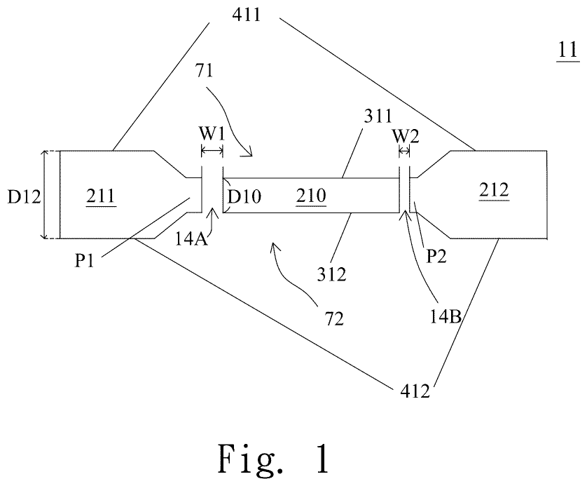

At first, please refer to FIG. 1, which schematically shows a cross sectional diagram of an oscillator crystal structure having internal cut-off region in accordance with a first embodiment of the present invention. As shown in FIG. 1, a structural crystal diagram of the disclosed oscillator crystal structure 11 includes a crystal main region 210, a first adjacent region 211 and a second adjacent region 212. The crystal main region 210 includes an upper surface 311 and a lower surface 312, which is opposite to the upper surface 311. The first adjacent region 211 is disposed adjacent to one side of the crystal main region 210. The second adjacent region 212 is opposite to the first adjacent region 211 and the second adjacent region 212 is disposed adjacent to another side of the crystal main region 210. Please refer to FIG. 1, the first adjacent region 211 and the second adjacent region 212 includes a top surface 411 and a bottom surface 412. A maximum thickness D12 of the first adjacent region 211 and the second adjacent region 212 is defined in between the top surface 411 and the bottom surface 412. It can be apparently seen that the maximum thickness D12 of the first adjacent region 211 and the second adjacent region 212 is greater than a crystal thickness D10 of the crystal main region 210. By such structural features, an upper cavity 71 is formed between the top surface 411 of the first adjacent region 211 and the second adjacent region 212 and the upper surface 311 of the crystal main region 210. Meanwhile, a lower cavity 72 is formed between the bottom surface 412 of the first adjacent region 211 and the second adjacent region 212 and the lower surface 312 of the crystal main region 210. In addition, a cut-off region 14A is formed between the crystal main region 210 and its neighbouring first adjacent region 211, such that the crystal main region 210 and the first adjacent region 211 are separated due to the cut-off region 14A.

Additionally, another cut-off region 14B is formed between the crystal main region 210 and its neighbouring second adjacent region 212, such that the crystal main region 210 and the second adjacent region 212 are separated due to the cut-off region 14B. According to the first embodiment of the present invention, the disclosed oscillator crystal structure 11 is illustrated as including two internal cut-off regions 14A and 14B. However, the present invention is certainly not limited thereto. According to the feasible technical contents of the present invention, at least one, or more than one internal cut-off region is allowed to be disposed in the proposed oscillator crystal structure. The present invention is not limited by the number of cut-off region to be formed, or limited by the location where the cut-off region is precisely disposed. It should be understood that modifications regarding the number, width, and/or location of the formed cut-off region within the proposed oscillator crystal structure are appropriately allowed by practitioners who are skilled in the technical field, depending on actual design specifications and requirements. Based on the spirits of the present invention, these modifications should still fall within the scope of the present invention, so the present invention covers its modifications and equivalent embodiments.

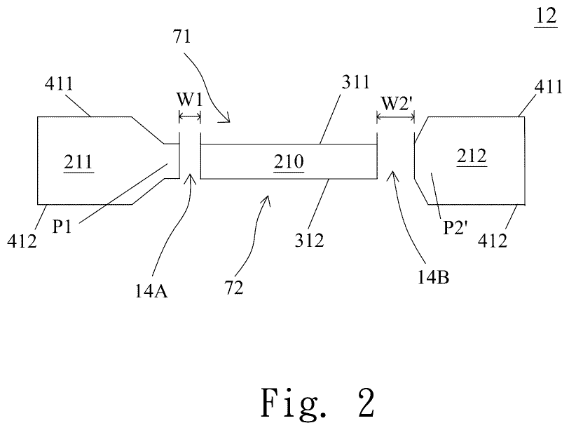

To be specific, the disclosed cut-off regions 14A and 14B are configured to be extending from the upper surface 311 to the lower surface 312 of the crystal main region 210 of the oscillator crystal structure 11, forming a penetration between the upper surface 311 and the lower surface 312. According to the present invention, the disclosed cut-off regions 14A and 14B are formed by adopting a dry etching process or a wet etching process. In addition, a width of the disclosed cut-off regions 14A and 14B are adjustable. For instance, as shown in FIG. 1, when the cut-off region 14A has a first width W1 and the cut-off region 14B has a first width W2, it can be seen that the first adjacent region 211 has a protrusion P1 which is closed to the crystal main region 210, and the second adjacent region 212 has a protrusion P2 which is closed to the crystal main region 210. Nevertheless, as mentioned earlier, the width of the disclosed cut-off region is adjustable. Please refer to FIG. 2, which schematically shows a cross sectional diagram of another oscillator crystal structure having internal cut-off region in accordance with a second embodiment of the present invention. As shown in FIG. 2, the disclosed oscillator crystal structure 12 includes a crystal main region 210, a first adjacent region 211, a second adjacent region 212, an upper cavity 71, a lower cavity 72 and cut-off regions 14A and 14B. What differs from the previous first embodiment is that, according to the second embodiment of the present invention, the cut-off region 14B has a width W2′ which is slightly wider than the first width W2. Under such a circumstance, compared to the previous protrusion P2 in FIG. 1, the protrusion P2′ of the second adjacent region 212 in the second embodiment in FIG. 2 will be slightly smaller and has a shallower protruding width.

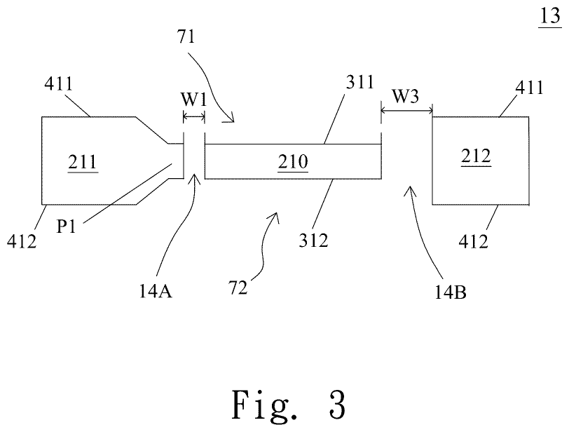

Moreover, FIG. 3 further discloses a cross sectional diagram of another oscillator crystal structure having internal cut-off region in accordance with a third embodiment of the present invention. As shown in FIG. 3, the disclosed oscillator crystal structure 13 includes a crystal main region 210, a first adjacent region 211, a second adjacent region 212, an upper cavity 71, a lower cavity 72 and cut-off regions 14A and 14B. However, in the third embodiment, the cut-off region 14B has an even wider width W3, such that the second adjacent region 212 has a straight edge which is closed to the crystal main region 210. Under such a circumstance, no protrusion is made. And such embodiment is also implementable. The applicants of the present invention have disclosed the above three variant embodiments in order to fully illustrate many possible variations in which the cut-off region can be provided according to the present invention. In general, these embodiments are illustrative, and not intend to limit the claim scope of the present invention. The main spirits of the present invention lie in forming at least one internal cut-off region in the oscillator crystal structure. In the following paragraphs, the applicants of the present invention proceed to provide a wafer-level-package (WLP) structure of such an improved oscillator crystal structure, and by providing related data, it will be proven that the WLP structure thereof performs better efficiencies, and is advantageous of solving the current heat stress, frequency offset issues existing in the current technologies.

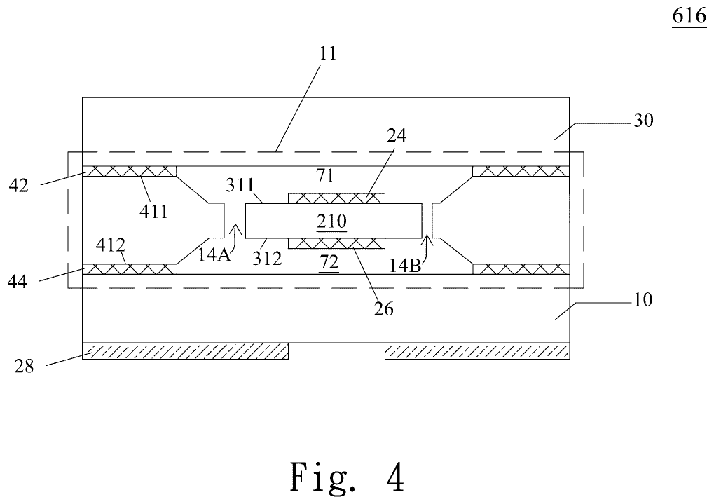

Please refer to FIG. 4, which schematically shows a cross sectional diagram of an oscillator wafer-level-package (WLP) structure encapsulating the oscillator crystal structure in FIG. 1. The disclosed oscillator wafer-level-package structure 616 includes a bottom layer 10, a capping layer 30 and the oscillator crystal structure 11 as mentioned in the first embodiment in FIG. 1. By adopting the bottom layer 10 and the capping layer 30, the oscillator crystal structure 11 is encapsulated. According to the embodiment of the present invention, the oscillator crystal structure 11, for example, may include an AT-cut quartz crystal resonator, a tuning-fork type (U-shaped) quartz crystal resonator, or other mechanical resonance type resonators.

The bottom layer 10 includes an upper plane, and the capping layer includes a lower plane. The oscillator crystal structure 11 is disposed between the bottom layer 10 and the capping layer 30, and the oscillator crystal structure 11 is in contact with the upper plane of the bottom layer and the lower plane of the capping layer 30. As we have described in the first embodiment, the oscillator crystal structure 11 includes a crystal main region 210, a first adjacent region 211, a second adjacent region 212 and at least one internal cut-off regions 14A and 14B. As shown in FIG. 1, the upper cavity 71 is formed between the top surface 411 of the first adjacent region 211 and the second adjacent region 212 and the upper surface 311 of the crystal main region 210. The lower cavity 72 is formed between the bottom surface 412 of the first adjacent region 211 and the second adjacent region 212 and the lower surface 312 of the crystal main region 210. Therefore, when forming the WLP structure, the upper cavity 71 is sealed between the upper surface 311 of the crystal main region 210 and the lower plane of the capping layer 30. Meanwhile, the lower cavity 72 is sealed between the lower surface 312 of the crystal main region 210 and the upper plane of the bottom layer 10. According to the embodiment of the present invention, the sealing internal environment can be vacuum or filled with helium, for example, such that by directly bonding the capping layer 30 with the bottom layer 10, the oscillator crystal structure 11 is sealed and packaged between the lower plane of the capping layer 30 and the upper plane of the bottom layer 10. And therefore, the oscillator wafer-level-package structure 616 encapsulating the oscillator crystal structure 11 is obtained.

In general, an upper electrode and a lower electrode can be respectively formed on an upper surface and a lower surface of the oscillator crystal structure 11 as exciting electrodes, and conductive bumps are electrically connected thereto to provide electrical connections to a plurality of metal pads on the bottom layer 10, so as to excite and activate the oscillator crystal structure 11 (which will be discussed later). In one embodiment of the present invention, the above-mentioned conductive bumps, for instance, can be made of metal, such as gold, copper, tin, silver, indium or an alloy of these materials. Alternatively, the conductive bumps can also be made of conductive adhesives composed of silver particles and resin.

As can be seen, an upper seal ring 42 is formed between the lower plane of the capping layer 30 and the top surface 411 of the oscillator crystal structure 11. A lower seal ring 44 is formed between the upper plane of the bottom layer 10 and the bottom surface 412 of the oscillator crystal structure 11. The upper seal ring 42 and the lower seal ring 44 are respectively surrounding the crystal main region 210 of the oscillator crystal structure 11 such that the oscillator crystal structure 11 is sealed in between the capping layer 30 and the bottom layer 10 by employing the upper seal ring 42 and the lower seal ring 44. Therefore, when the upper seal ring 42 and the capping layer 30 are jointed with the lower seal ring 44 and the bottom layer 10 along with the oscillator crystal structure 11, the present invention achieves to seal the oscillator crystal structure 11 there in between and provide better impermeability. Meanwhile, an upper electrode and a lower electrode can be respectively formed on the upper surface and the lower surface of the oscillator crystal structure 11 as an upper exciting electrode 24 and a lower exciting electrode 26 as shown in the figure, so as to excite and activate the oscillator crystal structure 11. In other words, as referring to the embodiment as illustrated in FIG. 4, by jointing the upper seal ring 42 and the capping layer 30 together with the lower seal ring 44 and the bottom layer 10, the oscillator crystal structure 11 can be sealed inside, wherein the sealing internal environment can be vacuum or filled with helium, for example.

In view of an U.S. patent number U.S. Pat. No. 7,608,986 which has disclosed a Quartz crystal resonator, such prior art was related to a wafer-level-package structure, in which an upper cap and a lower base made of blue plate glass are anodic bonded with the quartz crystal so as to form a sandwich structure. Nevertheless, regarding the sandwich structure, wherein the thermal expansion coefficients of the base material and the quartz are different, the internal quartz crystal will encounter thermal stress when the temperature changes, which accordingly makes the piezoelectric oscillation frequency shift along with the changed temperature. Therefore, to avoid such issues, the cut corners of the quartz crystal wafer and the thermal expansion coefficients of the materials for fabricating the upper cap and the lower base must be carefully chosen, and sophisticated designs and regulations must be taken into considerations in the prior arts. However, it has been acknowledged that such actions would have increased the fabrication cost and human resources requirements greatly and dramatically. Therefore, in order to avoid such foregoing shortcomings as mentioned above, including high fabrication cost and unstable supply resources when using the current ceramic material packaging technology as well as the thermal stress issue caused by the sandwich-shaped package structure are still not effectively solved, the present invention is aimed to design the capping layer 30 and the bottom layer 10 to have similar thermal expansion coefficients, in order to avoid the thermal stress issue when performing sealing and thus can meet the optimization of structural stress intensity. Specifically, the thermal expansion coefficient of the capping layer 30 and the bottom layer 10 of the present invention can be controlled in a range between 2*10-7/K and 9*10-7/K. Furthermore, in one embodiment of the present invention, a material of all the proposed capping layer 30, oscillator crystal structure 11 and bottom layer 10 can be selected as quartz to have an optimal thermal stress result when realizing the sealing package structure.

On the other hand, the upper exciting electrode 24 is disposed in the sealed upper cavity 71, and the lower exciting electrode 26 is disposed in the sealed lower cavity 72. As can be seen, a bottom metal layer 28 is further formed on an underneath layer of the bottom layer 10, and by providing at least one via hole penetrating through the bottom layer 10, it is believed that the bottom metal layer 28 is able to extend upward to fill the at least one via hole and form at least one metal pillar so as to electrically connect to the upper exciting electrode 24, the lower exciting electrode 26 and the bottom metal layer 28 for providing signal inputs and outputs. By employing such configurations, it provides the signal inputs and outputs (I/O) of the oscillator wafer-level-package structure 616. According to the embodiment of the present invention, a material of the bottom metal layer 28 can be, and yet not limited to, copper (Cu).

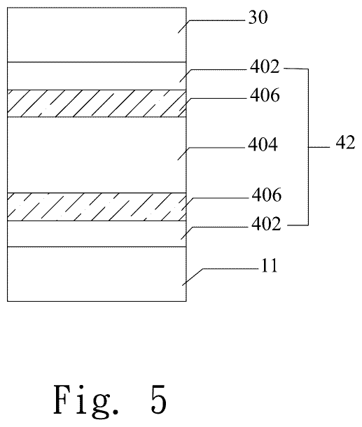

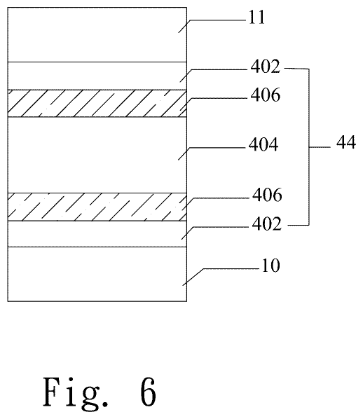

In addition, regarding the configurations of the above-mentioned upper seal ring 42 and lower seal ring 44, please find FIG. 5 and FIG. 6, which respectively shows a cross sectional view of the upper seal ring 42 and the lower seal ring 44 according to the embodiment of the present invention. Since one another objective of the present invention is to prevent interface diffusion, please refer to FIG. 5, in which the upper seal ring 42 is provided, comprising two interface metal layers 402 and one connecting metal layer 404, wherein the two interface metal layers 402 are connected with the capping layer 30 and the oscillator crystal structure 11, respectively. In addition, a diffusion barrier 406 is further disposed between each of the interface metal layers 402 and the connecting metal layer 404. For instance, the diffusion barrier 406 can be made of a material selected from the group consisting of ruthenium (Ru), titanium (Ti) or an alloy of Ru and Ti, organic polymers, and oxides. Similarly, please refer to FIG. 6. It is illustrated that the lower seal ring 44 comprises two interface metal layers 402 and one connecting metal layer 404, wherein the two interface metal layers 402 are connected with the bottom layer 10 and the oscillator crystal structure 11, respectively. And also, a diffusion barrier 406 is further disposed between each of the interface metal layers 402 and the connecting metal layer 404. The diffusion barrier 406, for example, can be made of a material selected from the group consisting of ruthenium (Ru), titanium (Ti) or an alloy of Ru and Ti, organic polymers, and oxides. By designing such configurations of the above-mentioned interface metal layers 402, connecting metal layer 404 and diffusion barrier 406 between the interface metal layers 402 and the connecting metal layer 404, the present invention achieves in effectively avoiding the interface diffusion generated in the upper seal ring 42 and in the lower seal ring 44.

To be specific, according to one preferred embodiment of the present invention, the interface metal layers 402 can be made of chromium (Cr) and each of the interface metal layers 402 has a thickness of 10 nanometers (nm), for instance. The connecting metal layer 404 can be made of gold (Au), tin (Sn) or an alloy of Au and Sn, and has a thickness of 30 nm to 70 nm, for instance. And the diffusion barrier 406 disposed there in between the interface metal layer 402 and the connecting metal layer 404, for instance, can have a thickness of 10 nm. According to the technical contents and solutions proposed by the present invention, people having ordinary knowledge backgrounds and skilled in the art are allowed to vary their own design patterns depending on the actual implementation fields and practice products, nevertheless, which still fall into the scope of the present invention. The several illustrative embodiments of the present invention provided in the foregoing paragraphs are described to explain the main technical features of the present invention so well that those skilled in the art are able to understand and implement according to the present invention. The present invention is certainly not limited thereto these illustrative embodiments.

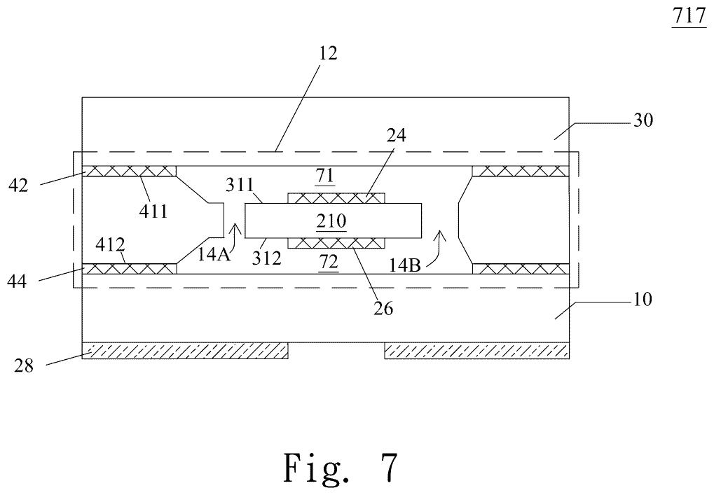

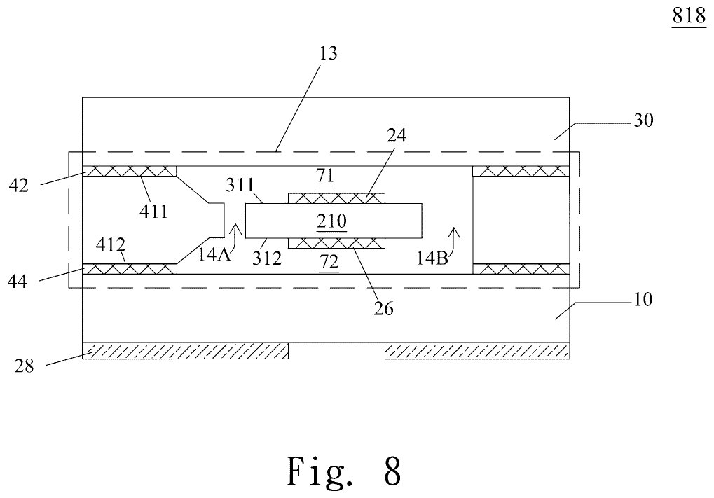

FIG. 7 schematically shows a cross sectional diagram of another oscillator wafer-level-package (WLP) structure encapsulating the oscillator crystal structure in FIG. 2. The disclosed oscillator wafer-level-package structure 717 includes a bottom layer 10, a capping layer 30 and the oscillator crystal structure 12 as mentioned in the second embodiment in FIG. 2. By adopting the bottom layer 10 and the capping layer 30, the oscillator crystal structure 12 is encapsulated. Moreover, FIG. 8 schematically shows a cross sectional diagram of one another oscillator wafer-level-package (WLP) structure encapsulating the oscillator crystal structure in FIG. 3. The disclosed oscillator wafer-level-package structure 818 includes a bottom layer 10, a capping layer 30 and the oscillator crystal structure 13 as mentioned in the third embodiment in FIG. 3. By adopting the bottom layer 10 and the capping layer 30, the oscillator crystal structure 13 is encapsulated. As a result, it is believed that in general, those skilled in the art and having general knowledge are able to make appropriate modifications or variations with respective to the technical contents disclosed in the present invention without departing from the spirits of the present invention. The present invention is not restricted by the certain limited configurations and/or structural diagrams disclosed in the embodiments of the present invention. As such, it is believed that the modifications or variations should still fall into the scope of the present invention, and the present invention covers the modifications and its equality.

To sum above, in view of the multiple embodiments disclosed in the present invention, it can be obtained that the internal thermal stress distribution of the wafer-level packaging structure can be effectively reduced from a traditional 10.99 MPa to the current 2.41 MPa through thermal stress simulation analysis data. It shows that when the oscillator crystal structure is modified to have internal cut-off region, a much better internal thermal stress distribution can be obtained. Meanwhile, the applicants of the present invention also provide the Table 1 below for your references, in which the Table 1 shows comparative analysis data under 76.8M frequency measurement based on a traditional oscillator crystal package structure in the prior art in related to a modified oscillator crystal package structure of the present invention.

TABLE 1

| | | the present |
|---|---|---|
| | prior art | invention |
| Resistance | 28.8Ω | 18.2Ω |
| Quality factor (Q) | 19717 | 59638 |

From Table 1, it can also be confirmed that when the oscillator crystal structure is modified to have internal cut-off region, better device characteristics, including: lower resistance and better quality factor can be achieved. Furthermore, when performing frequency measurement, it is also believed that the wafer-level package structure formed by the present invention is able to significantly reduce frequency deviation issues caused by stress transfer due to any applied external forces.

As a result, in view of above, it is obvious that the present invention discloses an oscillator wafer-level-package structure and oscillator crystal structure having internal cut-off region thereof. By employing the technical solution of the present invention, it solves the restricted manufacturing process problems occurring in the prior arts due to the conventional cavity which requires to be directly configured on the surface of the bottom layer in the traditional WLP structure. And in addition, the present invention solves the obstacles (including high product cost and unstable supply, etc.), that only ceramic material could be used for forming package structures, and thus improves the thermal stress caused by the sandwich-shaped package structure by adopting the same material for forming the capper layer, the oscillator crystal structure, and the bottom layer of the WLP structure. As a result, when compared to the plurality of prior arts, the present invention is believed to provide better device properties and electrical characteristics. Additionally, a diffusion barrier is also proposed in the present invention for effectively preventing interface diffusion problems. And therefore, it is evident that the present invention apparently shows much more effective performances than before. As such, it is believed that the present invention is definitely instinct, effective and highly competitive for semiconductor technologies and industries in the market nowadays, whereby having extraordinary availability and competitiveness for future industrial developments and being in condition for early allowance.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

1. An oscillator crystal structure having internal cut-off region, comprising:
a crystal main region, including an upper surface and a lower surface opposite to the upper surface;
a first adjacent region, being disposed adjacent to one side of the crystal main region; and
a second adjacent region, opposite to the first adjacent region and disposed adjacent to another side of the crystal main region;
wherein a maximum thickness of the first adjacent region and the second adjacent region is greater than a crystal thickness of the crystal main region, such that an upper cavity is formed between a top surface of the first adjacent region and the second adjacent region and the upper surface of the crystal main region, and a lower cavity is formed between a bottom surface of the first adjacent region and the second adjacent region and the lower surface of the crystal main region, and wherein at least one cut-off region is formed between the crystal main region and the first or the second adjacent region, such that the crystal main region and the first or the second adjacent region are separated.

2. The oscillator crystal structure having internal cut-off region according to claim 1, wherein the at least one cut-off region is formed between the crystal main region and the first adjacent region, such that the crystal main region and the first adjacent region are separated.

3. The oscillator crystal structure having internal cut-off region according to claim 1, wherein the at least one cut-off region is formed between the crystal main region and the second adjacent region, such that the crystal main region and the second adjacent region are separated.

4. The oscillator crystal structure having internal cut-off region according to claim 1, wherein the at least one cut-off region is formed between the crystal main region and the first adjacent region and between the crystal main region and the second adjacent region, such that the crystal main region, the first adjacent region and the second adjacent region are separated.

5. The oscillator crystal structure having internal cut-off region according to claim 1, wherein the at least one cut-off region is configured to be extending from the upper surface to the lower surface of the crystal main region, forming a penetration between the upper surface and the lower surface.

6. The oscillator crystal structure having internal cut-off region according to claim 1, wherein a width of the at least one cut-off region is adjustable, and when the at least one cut-off region has a first width, the first adjacent region or the second adjacent region has a protrusion which is closed to the crystal main region.

7. The oscillator crystal structure having internal cut-off region according to claim 6, wherein when the at least one cut-off region has a second width, the first adjacent region or the second adjacent region has a straight edge which is closed to the crystal main region.

8. The oscillator crystal structure having internal cut-off region according to claim 7, wherein the second width is greater than the first width.

9. The oscillator crystal structure having internal cut-off region according to claim 1, wherein the at least one cut-off region is formed by adopting a dry etching process or a wet etching process.

10. The oscillator crystal structure having internal cut-off region according to claim 1, wherein a material of the crystal main region, the first adjacent region and the second adjacent region is quartz.

11. An oscillator wafer-level-package structure, comprising:
a bottom layer, including an upper plane;
a capping layer, including a lower plane; and
an oscillator crystal structure, disposed between the bottom layer and the capping layer and in contact with the upper plane of the bottom layer and the lower plane of the capping layer, wherein the oscillator crystal structure comprises:
a crystal main region, including an upper surface and a lower surface opposite to the upper surface;
a first adjacent region, being disposed adjacent to one side of the crystal main region; and
a second adjacent region, opposite to the first adjacent region and disposed adjacent to another side of the crystal main region;
wherein a maximum thickness of the first adjacent region and the second adjacent region is greater than a crystal thickness of the crystal main region, such that an upper cavity is formed between a top surface of the first adjacent region and the second adjacent region and the upper surface of the crystal main region, and a lower cavity is formed between a bottom surface of the first adjacent region and the second adjacent region and the lower surface of the crystal main region, and wherein at least one cut-off region is formed between the crystal main region and the first or the second adjacent region, such that the crystal main region and the first or the second adjacent region are separated, and wherein the upper cavity is sealed between the upper surface of the crystal main region and the lower plane of the capping layer, the lower cavity is sealed between the lower surface of the crystal main region and the upper plane of the bottom layer, and the oscillator crystal structure is sealed and packaged between the capping layer and the bottom layer.

12. The oscillator wafer-level-package structure according to claim 11, further comprising:
an upper seal ring, which is formed between the lower plane of the capping layer and the top surface of the first adjacent region and the second adjacent region of the oscillator crystal structure; and
a lower seal ring, which is formed between the upper plane of the bottom layer and the bottom surface of the first adjacent region and the second adjacent region of the oscillator crystal structure, wherein the upper seal ring and the lower seal ring are respectively surrounding the crystal main region of the oscillator crystal structure such that the oscillator crystal structure is sealed in between the capping layer and the bottom layer by employing the upper seal ring and the lower seal ring.

13. The oscillator wafer-level-package structure according to claim 12, wherein the upper seal ring comprises two interface metal layers and a connecting metal layer, the two interface metal layers are respectively connected with the lower plane of the capping layer and the top surface of the first adjacent region and the second adjacent region of the oscillator crystal structure, and wherein a diffusion barrier is further disposed between each of the two interface metal layers and the connecting metal layer, and the diffusion barrier is made of a material selected from a group consisting of ruthenium (Ru), titanium (Ti) or an alloy of Ru and Ti, organic polymers, and oxides.

14. The oscillator wafer-level-package structure according to claim 12, wherein the lower seal ring comprises two interface metal layers and a connecting metal layer, the two interface metal layers are respectively connected with the upper plane of the bottom layer and the bottom surface of the first adjacent region and the second adjacent region of the oscillator crystal structure, and wherein a diffusion barrier is further disposed between each of the two interface metal layers and the connecting metal layer, and the diffusion barrier is made of a material selected from a group consisting of ruthenium (Ru), titanium (Ti) or an alloy of Ru and Ti, organic polymers, and oxides.

15. The oscillator wafer-level-package structure according to claim 13, wherein a material of the two interface metal layers is chromium (Cr).

16. The oscillator wafer-level-package structure according to claim 13, wherein a material of the connecting metal layer is gold (Au), tin (Sn) or an alloy of Au and Sn.

17. The oscillator wafer-level-package structure according to claim 11, wherein an upper exciting electrode and a lower exciting electrode are respectively formed on the upper surface and the lower surface of the oscillator crystal structure, and the upper exciting electrode and the lower exciting electrode are respectively disposed in the sealed upper cavity and in the sealed lower cavity, and wherein a bottom metal layer is formed on an underneath layer of the bottom layer, at least one via hole penetrates through the bottom layer such that the bottom metal layer extends upward to fill the at least one via hole and form at least one metal pillar so as to electrically connect to the upper exciting electrode, the lower exciting electrode and the bottom metal layer for providing signal inputs and outputs.

18. The oscillator wafer-level-package structure according to claim 17, wherein a material of the bottom metal layer is copper (Cu).

19. The oscillator wafer-level-package structure according to claim 11, wherein a thermal expansion coefficient of the capping layer and the bottom layer is in a range between 2*10-7/K and 9*10-7/K.

20. The oscillator wafer-level-package structure according to claim 11, wherein a material of the capping layer, the oscillator crystal structure and the bottom layer is quartz.

21. The oscillator wafer-level-package structure according to claim 11, wherein the at least one cut-off region is formed between the crystal main region and the first adjacent region, such that the crystal main region and the first adjacent region are separated.

22. The oscillator wafer-level-package structure according to claim 11, wherein the at least one cut-off region is formed between the crystal main region and the second adjacent region, such that the crystal main region and the second adjacent region are separated.

23. The oscillator wafer-level-package structure according to claim 11, wherein the at least one cut-off region is formed between the crystal main region and the first adjacent region and between the crystal main region and the second adjacent region, such that the crystal main region, the first adjacent region and the second adjacent region are separated.

24. The oscillator wafer-level-package structure according to claim 11, wherein the at least one cut-off region is configured to be extending from the upper surface to the lower surface of the crystal main region, forming a penetration between the upper surface and the lower surface.

25. The oscillator wafer-level-package structure according to claim 11, wherein a width of the at least one cut-off region is adjustable, and when the at least one cut-off region has a first width, the first adjacent region or the second adjacent region has a protrusion which is closed to the crystal main region.

26. The oscillator wafer-level-package structure according to claim 25, wherein when the at least one cut-off region has a second width, the first adjacent region or the second adjacent region has a straight edge which is closed to the crystal main region.

27. The oscillator wafer-level-package structure according to claim 26, wherein the second width is greater than the first width.

28. The oscillator wafer-level-package structure according to claim 11, wherein the at least one cut-off region is formed by adopting a dry etching process or a wet etching process.
